(19) United States
(12) Patent Application Publication
(10) Pub. No.: US 2007/0290710 A1
(43) Pub. Date: Dec. 20, 2007

(54) Liquid crystal display capable of hiding defective pixels and hiding method thereof

(75) Inventor: Shu-Wen Chuang, Taipei (TW)

Correspondence Address: BIRCH STEWART KOLASCH & BIRCH, PO BOX 747, FALLS CHURCH, VA, 22040-0747, US

(73) Assignee: INVENTEC CORPORATION

(21) Appl. No.: 11/453,798

(22) Filed: Jun. 16, 2006

(51) Int. Cl. G01R 31/00; G02F 1/13

(52) U.S. Cl. 324/770

(57) ABSTRACT

A liquid crystal display (LCD) capable of hiding a defective pixel and a hiding method thereof applicable for a display mode of a liquid crystal display screen are provided. The method comprises firstly providing a substrate, detecting and recording the address data of all defective pixel dots of the substrate, and interrupting the display signal of defective pixel dots in response to the address data of the defective pixel dots.

### BACKGROUND OF THE INVENTION

1. Field of Invention

The present invention relates to a liquid crystal display (LCD) capable of hiding defective pixels and a hiding method thereof, and more particularly, to an eliminable Thin Film Transistor-Liquid Crystal Display (TFT-LCD) and a hiding method thereof.

2. Related Art

The so-called liquid crystal is a kind of crystalline liquid. At present, the liquid crystal has been widely used in general electronic products as a technology for display devices since being investigated and developed. For a TFT-LCD, the key components include a glass substrate, a color filter array substrate, a polarizer sheet, a thin film transistor array substrate, a liquid crystal layer, an alignment film, a backlight module, an ITO conductive film, and so on. The TFT-LCD is further formed from other materials and chemical products demanded during manufacturing. The thin film transistor array substrate comprises multiple thin transistors arranged in array and pixel electrodes configured corresponding to each thin transistor, wherein the thin film transistor array substrate mainly consists of two polarizers and liquid crystal molecules sandwiched between the two polarizers. The status of a light beam penetrating through the two polarizers can be controlled through controlling the arrangement of the liquid crystal molecules, thereby required white spots and black spots are generated. Compared with a conventional cathode ray tube (CRT) which is thick and heavy, the structure of the LCD has the characteristics of lightness and thinness. Therefore, the LCD is developed and applied very rapidly, and is even almost the only choice, especially for some specific portable electronic products, such as notebooks, laptop computers, handheld personal computers (HPC), and electronic dictionaries. However, the LCD also has disadvantages especially in some display effects. For example, the view angle and contrast ratio are relatively poor compared with the conventional CRT. Therefore, the CRT display and the LCD are both used in computer displays, wherein CRT displays are used in most desktop computers, and LCDs are used in handheld computers or notebooks, such as super twist nematic (STN) LCDs and thin film transistor (TFT) LCDs.

Furthermore, a liquid crystal panel of an LCD is composed of millions of transistors, wherein multiple liquid crystal display units each consisting of three sub-display units “R, G, B” are arranged into a plane. However, during the manufacture of an LCD panel, dot defects may emerge due to process mistakes. The dot defects may be classified into bright defects and dark defects. At present, LCDs are classified into A grade, B grade, and C grade according to the total quantity of dot defects, i.e., white spots and black spots, thereby fixing a price. Therefore, LCDs of A grade, B grade, and C grade all have white spots, which degrade the color effect and further affect the purchase intention of consumers.

In view of the above, the TFT is employed in the standard architecture of an LCD television, and the white spots are caused by the color mixture of other surrounding black spots. For example, when an image is displayed in a gray-scale state, wherein Red, Green, and Blue are in half-color states, the display color is not affected if there are no black spots in the LCD television. But, if there are black spots in the LCD television, wherein the blue spot of one spot is a black spot, the quality of the LCD television will be degraded because only Green and Red operate to generate a yellow spot in this block.

At present, red (R), green (G), and blue (B) are mixed to produce a set of colors, and the effect of the colors is presented through the effect of pixels, thereby determining the color of the liquid crystal panel. However, as the size of the panel of the LCD television becomes increasingly lager, the particle size of a pixel does not become smaller but larger if the resolution of the panel is unchanged, such that the particle size of a pixel may be observed clearly by naked eyes. Therefore, one of R, G, or B in a pixel becomes a black spot or any two of R, G, or B become black spots, when the image is displayed, the quality of the frame is affected due to the color mixture and dot defects. Especially when the frame presents skin colors of human bodies, the defects of the image are particularly obvious.

Furthermore, the dot defects of a liquid crystal panel are repaired to be black dots with some methods in prior arts, wherein all of the methods all relate to hardware repair, such as conventional ROC Invention Patent Publication No. I230298 “Method for Eliminating White Spot Defects of Liquid Crystal Display and Structure Thereof” and ROC Invention Publication No. I232976 “Hiding Method for White Spot Defects of Liquid Crystal Display”. However, when the liquid crystal panel is repaired after produced, more manufacturing resources are wasted and the product cost is increased if the repair fails.

### SUMMARY OF THE INVENTION

Accordingly, the present invention provides a hiding method for a defective pixel. When a defective pixel dot appears, the address data of the defective pixel dot is detected for interrupting the display signal of the defective pixel dot, thereby solving the problems of the prior art.

In order to achieve the aforementioned object, the hiding method for a defective pixel disclosed by the present invention is applicable for a display mode of a liquid crystal display screen. The hiding method comprises firstly providing a substrate, wherein the substrate has a plurality of pixel dots each formed from three primary colors: Red, Green, and Blue; receiving a display data and outputting the display data on the substrate; displaying a frame through the three primary colors of a pixel dot; detecting the substrate and returning the address data of each defective pixel dot to the basic input/output system of the substrate; adjusting the basic input/output system to interrupt the display signal of the defective pixel dot in response to the address data of the defective pixel dot.

When a defective pixel dot, i.e., a black dot presented by the three primary colors: Red, Green, and Blue, in a display frame affects the quality of the frame, the display signal of the defective pixel dot is interrupted by means of software correction through the hiding method for a defective pixel provided by the present invention, thereby upgrading the image quality of an LCD. Even if consumers observe the LCD very closely when choosing and buying an LCD, the defective pixel dot of the LCD still cannot be seen, so the purchase intention is not affected.

Additionally, the corrected LCD has a better image quality, so the sales price of the corrected LCD may be raised. Furthermore, because a defective pixel is corrected by means of software correction instead of hardware repair, the risk of failure is lowered and no additional cost is necessary.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, and which thus is not limitative of the present invention, and wherein:

FIG. 1 is a flow chart of a hiding method for a defective pixel provided in the present invention; and

FIG. 2 is a block diagram of the LCD system provided in the present invention.

### DETAILED DESCRIPTION OF THE INVENTION

The hiding method for a defective pixel disclosed by the present invention is applicable for a display mode of a liquid crystal display screen. Through software correction, a defective pixel is detected for stopping outputting of the display signal of the defective pixel, thereby upgrading the quality of an image frame.

In order to the make the objects, structures, features, and functions of the present invention more comprehensible, an embodiment is described in detail below in accompany with the drawings. Both the foregoing general description and the following detailed description are exemplary, and are intended to provide a further explanation of the invention as claimed.

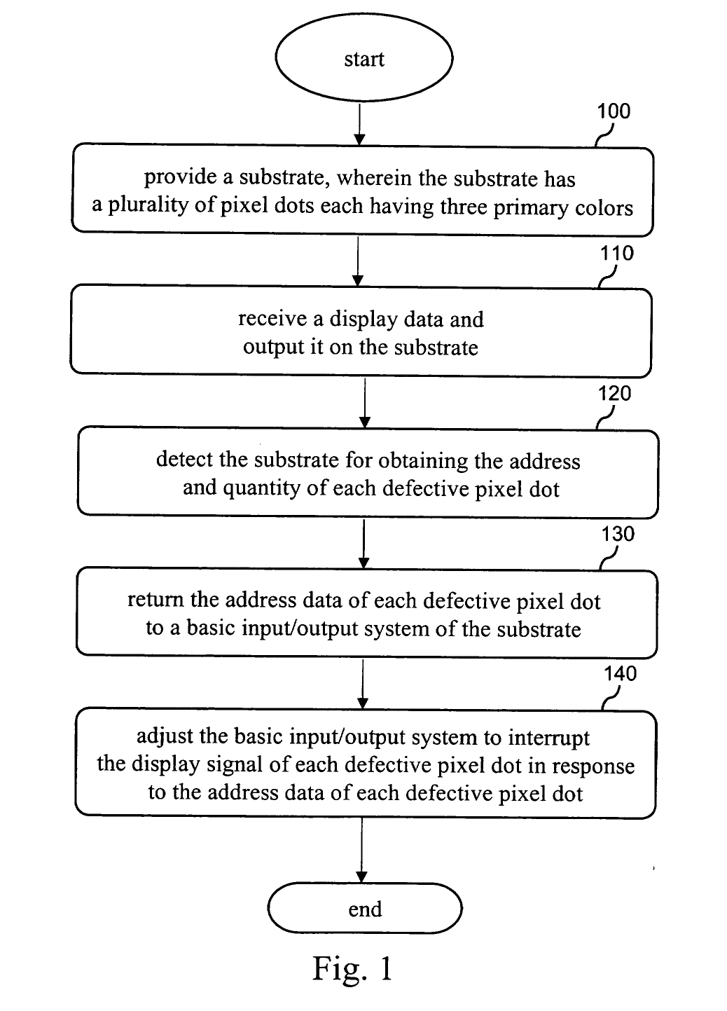

With reference to FIG. 1, it is a flow chart of the hiding method for a defective pixel provided by the present invention. The hiding method is applicable for a display mode of a liquid crystal display screen, such as a Thin Film Transistor-Liquid Crystal Display (TFT-LCD).

Firstly, a substrate is provided, wherein the substrate is an LCD with a plurality of pixel dots uniformly distributed on the panel and each having three display elements. The pixel dot comprises Red, Green, and Blue, and the required color of the pixel is produced through matching the three primary colors, i.e. Red, Green, and Blue. (Step 100)

When a display data is received, by use of the pixel dots on the LCD, the required color of the pixel is displayed through adjusting the three primary colors, i.e. Red, Green, and Blue, and a corresponding image is output on the LCD. (Step 110)

At the same time, the image output of the LCD is detected for seeking the address and quantity of the defective pixel dots, i.e., so-called dot defects, of the LCD (Step 120). The so-called dot defects refer to uncontrollable constantly bright spots or constantly dark spots. The dot defects are faults due to various factors during the manufacture of an LCD. For example, when particles fall into the panel, the panel is hurt and damaged by static electricity, or the process is not controlled effectively. The dot defects may be classified into white spots and black spots. A white spot refers to a constantly bright spot in any frame and is observed when the frame is switched to a black frame. A black spot refers to a constantly dark spot in any frame and is observed when the frame is switched to a white frame. Generally, the white spot is more unacceptable than the black spot, so manufactures may assure that no white spots exist and all white spots are modified into black spots before shipment. Additionally, certain panels, such as the liquid crystal panels of MVA and IPS, only have black spots instead of white spots. In view of the above, when dot defects exist in a panel, the quality of the output frame of the panel is affected, thereby affecting the purchase intention of consumers. Therefore, the manufactureres of the panels lower the prices of the panels with dot defects and classify the panels into three grades, A grade with no dot defects, B grade with less than three dot defects, and C grade with less than six dot defects. For example, when Red and Green are black spots, and only Blue may be controlled, at this time, the dot defect presents Blue in a white frame. It is more easy for people to observe dot defects in a panel with larger pixels.

Herein, after the substrate is detected by a basic input/output system 200, the address and quantity of all defective pixel dots on the panel are transmitted to the basic input/output system 200 of the substrate. (Step 130)

Finally, the control set of the basic input/output system 200 to the primary colors of each defective pixel dot is adjusted. According to the returned address data of the defective pixel dots, the basic input/output system 200 interrupts the display signals of each defective pixel dot, thereby stopping outputting of the display signals to the three primary colors, i.e. Red, Green, and Blue of the defective pixel dots. (Step 140) For example, when Blue presents a black spot, only Red and Green may be controlled and the dot defect presents Yellow when the frame is white. At this point, the control set of the basic input/output system to the primary colors of each defective pixel dot is adjusted, thereby stopping outputting Red signal and Green signal of the defective pixel dot. Thus, R, G, and B of the pixel all present black spots. At last, the defective pixel will not affect the overall effect.

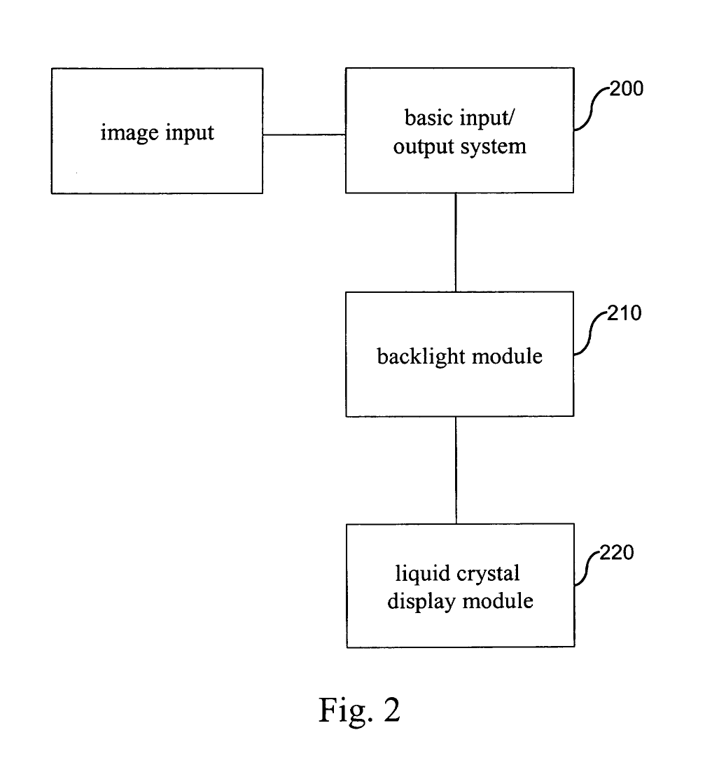

With reference to FIG. 2, it is a block diagram of the LCD system provided by the present invention. The LCD system is applicable for a TFT-LCD and hides a defective pixel dot by means of software correction. The LCD system comprises a liquid crystal display module 220, a backlight module 210, and a basic input/output system 200.

At present, the LCD is driven by means of active matrix addressing, which is an ideal device for achieving the liquid crystal display effect of high data density with extremely high resolution. In this method, the silicon transistor electrode manufactured through the thin-film technology controls the on and off of any pixel by scanning. That is, the nonlinear function of the thin film transistor is used to replace the nonlinear function of the liquid crystal that is not easily to be controlled. In a TFT-LCD, meshy tiny circuits are drawn on a conductive glass and the electrode is switched by the transistors arranged in a matrix. A control box is disposed at where any two circuits are crossed. Though a drive signal scans each pixel rapidly, only the selected pixel in the transistor matrix on the electrode may obtain sufficient voltage to drive a liquid crystal molecule, such that the molecular axis of the liquid crystal turns around to be “bright” and the unselected pixels are certainly “dark”. Thereby, the display function no longer depends on the effect of the liquid crystal electric field. The TFT-LCD mainly comprises a liquid crystal display module 220 and a backlight module 210, and further comprises a fluorescent tube, a light guide plate, polarizers, a filter panel, a glass substrate, an alignment film, liquid crystal materials, a thin film transistor, etc. Firstly, the LCD should use the backlight module 210, i.e., the light source emitted by the fluorescent tube, wherein the light source firstly passes through a polarizer, and then the liquid crystals; at this time, the arrangement of the liquid crystals further changes the angle of the light beam penetrating the liquid crystals. Then, the light should pass the color filter film and another polarizer in front. Therefore, in order to display the required colors, the primary colors, i.e. Red, Green, and Blue are controlled only through changing the magnitude of voltage driving the liquid crystals, thereby obtaining and displaying the required light intensity and color, and further forming color combinations with different shades on the liquid crystal display module 220.

Therefore, when a display frame is output on the liquid crystal module 220, the basic input/output system 200 is used to detect the address and quantity of each defective pixel dot of the liquid crystal module 220. The so-called dot defects refer to uncontrollable constantly bright spots or constantly dark spots, i.e., white spots or black spots, on the LCD. The dot defects are faults due to various factors during the manufacture of an LCD. According to the number of the dot defects, the panels are classified into three grades, A grade with no dot defects, B grade with less than three dot defects, and C grade with less than six dot defects. The number of the dot defects further determines the purchase intention of consumers, thereby affecting the sales price of the products. Then, the basic input/output system 200 may interrupt the display signal of defective pixel dots according to the address data of the defective pixel dots. Herein, the control set of the primary colors of the defective pixel dot are adjusted to stop outputting the signals of other display colors of the defective pixel dot. For example, when a dot defect appears on the liquid crystal display screen, wherein the dot defect may be the malfunction of the display element caused by a fault during manufacturing, the inharmonious color will degrade the quality of the frame, thereby lowering the sales price of the product. In the present invention, the primary colors, i.e. Red, Green, and Blue of the defective pixel dot are adjusted simultaneously to appear as black spots. Especially in LCD televisions, even having a B grade panel, the frame color of the overall LCD television will not be affected due to the defective pixel dots.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A hiding method for a defective pixel applicable for a display mode of a liquid crystal display screen, comprising:
providing a substrate, wherein the substrate has a plurality of pixel dots each consisting of Red, Green, and Blue;
receiving a display data and outputting it on the substrate;
detecting the substrate for obtaining the address and quantity of each defective pixel dot;
returning the address data of each defective pixel dot to a basic input/output system of the substrate; and
adjusting the basic input/output system to interrupt the display signal of each defective pixel dot in response to the address data of each defective pixel dot.

2. The hiding method for a defective pixel as claimed in claim 1, wherein the defective pixel dot is a black spot defective pixel.

3. The hiding method for a defective pixel as claimed in claim 1, wherein the defective pixel dot is a white spot defective pixel.

4. The hiding method for a defective pixel as claimed in claim 1, wherein the substrate is an active device substrate.

5. A liquid crystal display, comprising:
a liquid crystal display module for controlling the display content of the liquid crystal display;
a backlight module located behind the liquid crystal display module for illuminating the liquid crystal display to display the display content; and
a basic input/output system for detecting the address and quantity of each defective pixel dot of the liquid crystal display module, thereby interrupting the display signal of the defective pixel dot according to the address data of the defective pixel dot;
wherein each pixel dot is consisted of Red, Green, and Blue.

6. The liquid crystal display as claimed in claim 6, wherein the defective pixel dot is a black spot defective pixel.

7. The liquid crystal display as claimed in claim 6, wherein the defective pixel dot is a white spot defective pixel.
